(19) United States
(12) Patent Application Publication
(10) Pub. No.: US 2024/0021668 A1
(43) Pub. Date: Jan. 18, 2024

(54) SEMICONDUCTOR DEVICE

(71) Applicant: Japan Display Inc., Tokyo (JP)

(72) Inventors: Hajime WATAKABE, Tokyo (JP); Masashi TSUBUKU, Tokyo (JP); Toshinari SASAKI, Tokyo (JP); Takaya TAMARU, Tokyo (JP)

(73) Assignee: Japan Display Inc., Tokyo (JP)

(21) Appl. No.: 18/335,447

(22) Filed: Jun. 15, 2023

(30) Foreign Application Priority Data
Jul. 8, 2022 (JP) 2022-110322

(51) Int. Cl. H01L 29/04; H01L 21/02

(52) U.S. Cl. CPC H01L 29/04; H01L 21/02595; H01L 21/02609; H01L 21/02554; H01L 21/02129

(57) ABSTRACT

A semiconductor device includes an oxide semiconductor layer having a polycrystalline structure on an insulating surface, a gate electrode over the oxide semiconductor layer, and a gate insulating layer between the oxide semiconductor layer and the gate electrode. The oxide semiconductor layer includes a first region having a first crystal structure overlapping the gate electrode and a second region having a second crystal structure not overlapping the gate electrode. An electrical conductivity of the second region is larger than an electrical conductivity of the first region. The second crystal structure is identical to the first crystal structure.

This application claims the benefit of priority to Japanese Patent Application No. 2022-110322, filed on Jul. 8, 2022, the entire contents of which are incorporated herein by reference.

### FIELD

An embodiment of the present invention relates to a semiconductor device including an oxide semiconductor having a polycrystalline structure (Poly-OS).

### BACKGROUND

In recent years, a semiconductor device in which an oxide semiconductor is used for a channel instead of a silicon semiconductor such as amorphous silicon, low-temperature polysilicon, and single-crystal silicon, etc. has been developed (for example, see Japanese laid-open patent publication No. 2021-141338, Japanese laid-open patent publication No. 2014-099601, Japanese laid-open patent publication No. 2021-153196, Japanese laid-open patent publication No. 2018-006730, Japanese laid-open patent publication No. 2016-184771, and Japanese laid-open patent publication No. 2021-108405). A semiconductor device including such an oxide semiconductor can be formed with a simple structure and a low-temperature process, similar to a semiconductor device including amorphous silicon. The semiconductor device including the oxide semiconductor is known to have higher mobility than the semiconductor device including amorphous silicon.

### SUMMARY

A semiconductor device according to an embodiment of the present invention includes an oxide semiconductor layer having a polycrystalline structure on an insulating surface, a gate electrode over the oxide semiconductor layer, and a gate insulating layer between the oxide semiconductor layer and the gate electrode. The oxide semiconductor layer includes a first region having a first crystal structure overlapping the gate electrode and a second region having a second crystal structure not overlapping the gate electrode. An electrical conductivity of the second region is larger than an electrical conductivity of the first region. The second crystal structure is identical to the first crystal structure.

### BRIEF DESCRIPTION OF DRAWINGS

FIG. 1 is a schematic cross-sectional view showing a configuration of a semiconductor device according to an embodiment of the present invention.

FIG. 2 is a schematic plan view showing a configuration of a semiconductor device according to an embodiment of the present invention.

FIG. 3A is a schematic diagram illustrating a bonding state of a Poly-OS included in a second region of an oxide semiconductor layer of a semiconductor device according to an embodiment of the present invention.

FIG. 3B is a schematic diagram illustrating a bonding state of a Poly-OS included in a second region of an oxide semiconductor layer of a semiconductor device according to an embodiment of the present invention.

FIG. 3C is a schematic diagram illustrating a bonding state of a Poly-OS included in a second region of an oxide semiconductor layer of a semiconductor device according to an embodiment of the present invention.

FIG. 4 is a band diagram illustrating a band structure of a second region of an oxide semiconductor layer of a semiconductor device according to an embodiment of the present invention.

FIG. 5 is a flow chart showing a method for manufacturing a semiconductor device according to an embodiment of the present invention.

FIG. 6 is a schematic cross-sectional view showing a method for manufacturing a semiconductor device according to an embodiment of the present invention.

FIG. 7 is a schematic cross-sectional view showing a method for manufacturing a semiconductor device according to an embodiment of the present invention.

FIG. 8 is a schematic cross-sectional view showing a method for manufacturing a semiconductor device according to an embodiment of the present invention.

FIG. 9 is a schematic cross-sectional view showing a method for manufacturing a semiconductor device according to an embodiment of the present invention.

FIG. 10 is a schematic cross-sectional view showing a method for manufacturing a semiconductor device according to an embodiment of the present invention.

FIG. 11 is a schematic cross-sectional view showing a method for manufacturing a semiconductor device according to an embodiment of the present invention.

FIG. 12 is a schematic cross-sectional view showing a method for manufacturing a semiconductor device according to an embodiment of the present invention.

FIG. 13 is a schematic cross-sectional view showing a configuration of a semiconductor device according to an embodiment of the present invention.

FIG. 14 is a flow chart showing a method for manufacturing a semiconductor device according to an embodiment of the present invention.

FIG. 15 is a schematic cross-sectional view showing a method for manufacturing a semiconductor device according to an embodiment of the present invention.

FIG. 16 is a schematic cross-sectional view showing a method for manufacturing a semiconductor device according to an embodiment of the present invention.

FIG. 17 is a schematic cross-sectional view showing a method for manufacturing a semiconductor device according to an embodiment of the present invention.

FIG. 18 is a cross-sectional TEM image according to an example.

FIG. 19 shows a diffraction pattern of a semiconductor device according to an example observed using ultrafine electron diffraction.

FIG. 20 shows a diffraction pattern of a semiconductor device according to an example observed using ultrafine electron diffraction.

FIG. 21 shows a diffraction pattern of a semiconductor device according to an example observed using ultrafine electron diffraction.

FIG. 22 is a graph showing electrical characteristics of a semiconductor device according to an example.

FIG. 23A is a schematic diagram illustrating a bonding state of a second region of an oxide semiconductor layer of a conventional semiconductor device.

FIG. 23B is a schematic diagram illustrating a bonding state of a second region of an oxide semiconductor layer of a conventional semiconductor device.

FIG. 23C is a schematic diagram illustrating a bonding state of a second region of an oxide semiconductor layer of a conventional semiconductor device.

FIG. 23D is a schematic diagram illustrating a bonding state of a second region of an oxide semiconductor layer of a conventional semiconductor device.

FIG. 24 is a band diagram illustrating a band structure of a second region of an oxide semiconductor layer of a conventional semiconductor device.

FIG. 25 is a graph showing electrical characteristics of a semiconductor device according to a comparative example.

### DESCRIPTION OF EMBODIMENTS

In a semiconductor device including a conventional oxide semiconductor, the resistance of a source region and a drain region of an oxide semiconductor layer is not sufficiently reduced. Therefore, in the electrical characteristics of the semiconductor device, there is a problem that an on-current is lowered due to the parasitic resistance of the source region and the drain region.

In view of the above problem, one object of an embodiment of the present invention is to provide a semiconductor device in which an oxide semiconductor layer includes a source region and a drain region with sufficiently low resistance.

Each embodiment of the present invention is described below with reference to the drawings. The following disclosure is merely an example. A configuration that can be easily conceived by a person skilled in the art by appropriately changing the configuration of the embodiment while maintaining the gist of the invention is naturally included in the scope of the present invention. For the sake of clarity of description, the drawings may be schematically represented with respect to widths, thicknesses, shapes, and the like of the respective portions in comparison with actual embodiments. However, the shape shown is merely an example and does not limit the interpretation of the present invention. In this specification and each of the drawings, the same symbols are assigned to the same components as those described previously with reference to the preceding drawings, and a detailed description thereof may be omitted as appropriate.

In the specification, a direction from a substrate to an oxide semiconductor layer is referred to as “on” or “over”. Reversely, a direction from the oxide semiconductor layer to the substrate is referred to as “under” or “below”. As described above, for convenience of explanation, although the phrase “over (on)” or “below (under)” is used for explanation, for example, a vertical relationship between the substrate and the oxide semiconductor layer may be arranged in a different direction from that shown in the drawing. In the following description, for example, the expression “the oxide semiconductor layer on the substrate” merely describes the vertical relationship between the substrate and the oxide semiconductor layer as described above, and other members may be arranged between the substrate and the oxide semiconductor layer. Over or below means a stacking order in a structure in which multiple layers are stacked, and when it is expressed as a pixel electrode above a transistor, it may be a positional relationship where the transistor and the pixel electrode do not overlap each other in a plan view. On the other hand, when it is expressed as a pixel electrode vertically above a transistor, it means a positional relationship where the transistor and the pixel electrode overlap each other in a plan view.

In the specification, the terms “film” and “layer” may be interchangeably used.

The expressions “a includes A, B, or C”, “a includes any of A, B, and C”, and “a includes one selected from a group consisting of A, B, and C” do not exclude the case where a includes multiple combinations of A to C unless otherwise specified. Furthermore, these expressions do not exclude the case where a includes other elements.

In addition, the following embodiments may be combined with each other as long as there is no technical contradiction.

### First Embodiment

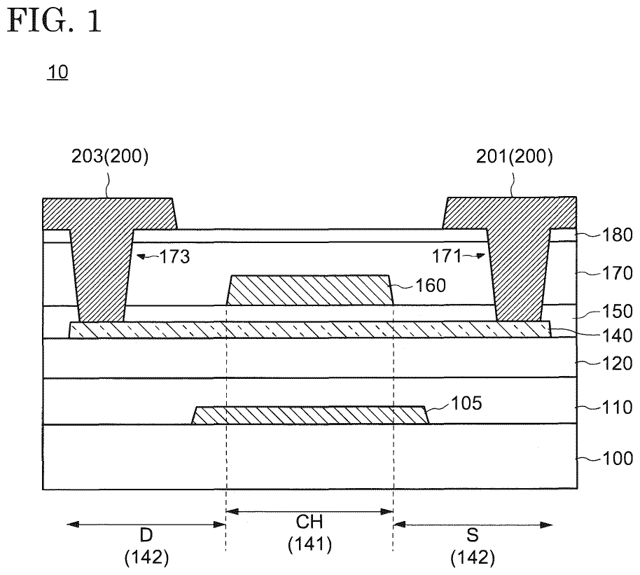

A semiconductor device 10 according to an embodiment of the present invention is described with reference to FIG. 1 to FIG. 12. The semiconductor device 10 can be used in, for example, a display device, an integrated circuit (IC) such as a micro-processing unit (MPU), or a memory circuit.

Here, “display device” refers to a structure configured to display an image using electro-optic layers. For example, the term display device may refer to a display panel including the electro-optic layer, or it may refer to a structure in which other optical members (e.g., polarizing member, backlight, touch panel, etc.) are attached to a display cell. The “electro-optic layer” can include a liquid crystal layer, an electroluminescence (EL) layer, an electrochromic (EC) layer, and an electrophoretic layer, as long as there is no technical contradiction. Therefore, the semiconductor device 10 according to an embodiment of the present invention can be applied to a display device including any electro-optic layer.

### [1. Configuration of Semiconductor Device 10]

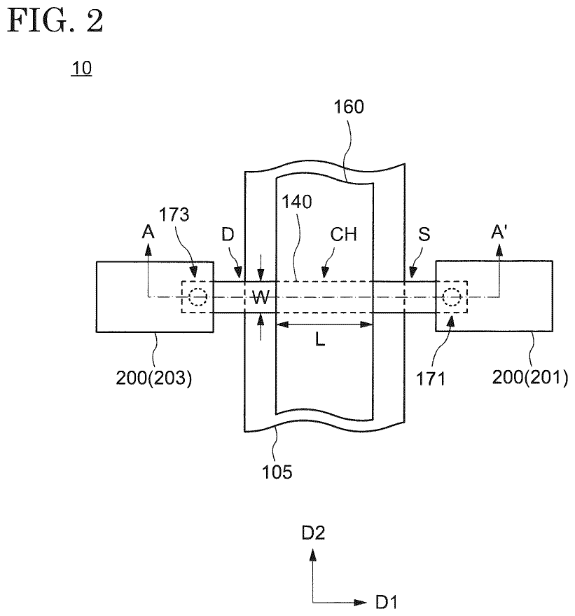

FIG. 1 is a schematic cross-sectional view showing a configuration of a semiconductor device 10 according to an embodiment of the present invention. FIG. 2 is a schematic plan view showing a configuration of a semiconductor device according to an embodiment of the present invention. Specifically, FIG. 1 is a cross-sectional view cut along the line A-A′ of FIG. 2.

As shown in FIG. 1, the semiconductor device 10 includes a substrate 100, a light shielding layer 105, a first insulating layer 110, a second insulating layer 120, an oxide semiconductor layer 140, a gate insulating layer 150, a gate electrode 160, a third insulating layer 170, a fourth insulating layer 180, a source electrode 201, and a drain electrode 203. The light shielding layer 105 is provided on the substrate 100. The first insulating layer 110 is provided on the substrate 100 to cover an upper surface and an end surface of the light shielding layer 105. The second insulating layer 120 is provided on the first insulating layer 110. The oxide semiconductor layer 140 is provided on the second insulating layer 120. The gate insulating layer 150 is provided on the second insulating layer 120 to cover an upper surface and an end surface of the oxide semiconductor layer 140. The gate electrode 160 is provided on the gate insulating layer 150 to overlap the oxide semiconductor layer 140. The third insulating layer 170 is provided on the gate insulating layer 150 to cover an upper surface and an end surface of the gate electrode 160. The fourth insulating layer 180 is provided on the third insulating layer 170. Opening portions 171 and 173 through which a part of the upper surface of the oxide semiconductor layer is exposed are provided in the gate insulating layer 150, the third insulating layer 170, and the fourth insulating layer 180. The source electrode 201 is provided on the fourth insulating layer 180 and inside the opening portion 171 and is in contact with the oxide semiconductor layer 140. Similarly, the drain electrode 203 is provided on the fourth insulating layer 180 and inside the opening portion 173 and is in contact with the oxide semiconductor layer 140. In addition, hereinafter, when the source electrode 201 and the drain electrode 203 are not particularly distinguished, they may be collectively referred to as a source/drain electrode 200.

The oxide semiconductor layer 140 is divided into a source area S, a drain area D, and a channel area CH based on the gate electrode 160. That is, the oxide semiconductor layer includes the channel region CH which overlaps the gate electrode 160 and the source region S and the drain region D which do not overlap the gate electrode 160. In the thickness direction of the oxide semiconductor layer 140, an edge portion of the channel region CH substantially coincides with an edge portion of the gate electrode 160. The channel region CH has properties of a semiconductor. Each of the source region S and the drain region D has properties of a conductor. Therefore, the electrical conductivities of the source region S and the drain region D are larger than the electrical conductivity of the channel region CH. The source electrode 201 and the drain electrode 203 are in contact with the source region S and the drain region D, respectively, and are electrically connected to the oxide semiconductor layer 140. Further, the oxide semiconductor layer 140 may have a single layer structure or a laminated structure.

In addition, hereinafter, the channel region CH may be referred to as a first region 141. Moreover, when the source region S and the drain region D are not particularly distinguished, the source region S or the drain region D may be referred to as a second region 142.

As shown in FIG. 2, each of the light shielding layer 105 and the gate electrode 160 has a predetermined width in a direction D1 and extends in a direction D2 orthogonal to the direction D1. A width of the light shielding layer 105 is greater than a width of the gate electrode 160 in the direction D1. The channel region CH completely overlaps the light shielding layer 105. In the semiconductor device 10, the direction D1 corresponds to the direction in which current flows from the source electrode 201 to the drain electrode 203 through the oxide semiconductor layer 140. Therefore, a length of the channel region CH in the direction D1 is a channel length L, and a width of the channel region CH in the direction D2 is a channel width W.

The substrate 100 can support each layer in the semiconductor device 10. For example, a rigid substrate with translucency such as a glass substrate, a quartz substrate, or a sapphire substrate can be used as the substrate 100. Further, a rigid substrate without translucency such as a silicon substrate can be used as the substrate 100. Furthermore, a flexible substrate with translucency such as a polyimide resin substrate, an acrylic resin substrate, a siloxane resin substrate, or a fluorine resin substrate can be used as the substrate 100. In order to improve the heat resistance of the substrate 100, impurities may be introduced into the resin substrate. In addition, a substrate in which a silicon oxide film or a silicon nitride film is formed over the rigid substrate or the flexible substrate described above can be used as the substrate 100.

The light shielding layer 105 can reflect or absorb external light. As described above, since the light shielding layer 105 has a larger area than the channel region CH of the oxide semiconductor layer 140, the light shielding layer 105 can block external light entering the channel region CH. For example, aluminum (Al), copper (Cu), titanium (Ti), molybdenum (Mo), tungsten (W), or alloys or compounds thereof can be used for the light shielding layer 105. Further, the light shielding layer 105 may not necessarily include a metal when conductivity of the light shielding layer 105 is not required. For example, a black matrix made of black resin can be used for the light shielding layer 105. Furthermore, the light shielding layer 105 may have a single layer structure or a laminated structure. For example, the light shielding layer 105 may have a laminated structure of a red color filter, a green color filter, and a blue color filter.

The first insulating layer 110, the second insulating layer 120, the third insulating layer 170, and the fourth insulating layer 180 can prevent impurities from diffusing into the oxide semiconductor layer 140. Specifically, the first insulating layer 110 and the second insulating layer 120 can prevent diffusion of impurities contained in the substrate 100, and the third insulating layer 170 and the fourth insulating layer 180 can prevent diffusion of impurities (for example, water) entering from the outside. For example, silicon oxide (SiOₓ), silicon oxynitride (SiOₓN_{y}), silicon nitride (SiNₓ), silicon nitride oxide (SiNₓO_{y}), aluminum oxide (AlOₓ), aluminum oxynitride (AlOₓN_{y}), aluminum nitride oxide (AlNₓO_{y}), or aluminum nitride (AlNₓ) and the like are used for each of the first insulating layer 110, the second insulating layer 120, the third insulating layer 170, and the fourth insulating layer 180. Here, silicon oxynitride (SiOₓN_{y}) and aluminum oxynitride (AlOₓ N_{y}) are a silicon compound and an aluminum compound, respectively, that contain a smaller proportion (x>y) of nitrogen (N) than oxygen (O). Silicon nitride oxide (SiNₓO_{y}) and aluminum nitride oxide (AlNₓO_{y}) are a silicon compound and an aluminum compound, respectively, that contain a smaller proportion (x>y) of oxygen than nitrogen. Further, each of the first insulating layer 110, the second insulating layer 120, the third insulating layer 170, and the fourth insulating layer 180 may have a single layer structure or a laminated structure.

Further, each of the first insulating layer 110, the second insulating layer 120, the third insulating layer 170, and the fourth insulating layer 180 may have a planarization function or a function of releasing oxygen by a heat treatment. For example, when the second insulating layer 120 has a function of releasing oxygen by a heat treatment, oxygen is released from the second insulating layer 120 by the heat treatment performed in the manufacturing process of the semiconductor device 10, and the released oxygen can be supplied to the oxide semiconductor layer 140.

The gate electrode 160, the source electrode 201, and the drain electrode 203 are conductive. For example, copper (Cu), aluminum (Al), titanium (Ti), chromium (Cr), cobalt (Co), nickel (Ni), molybdenum (Mo), hafnium (Hf), tantalum (Ta), tungsten (W), or bismuth (Bi), or alloys or compounds thereof can be used for each of the gate electrode 160, the source electrode 201, and the drain electrode 203. Each of the gate electrode 160, source electrode 201, and drain electrode 203 may have a single layer structure or a laminated structure.

The gate insulating layer 150 includes an oxide having insulating properties. Specifically, silicon oxide (SiOₓ), silicon oxynitride (SiOₓN_{y}), aluminum oxide (AlOₓ), aluminum oxynitride (AlOₓN_{y}), or the like is used for the gate insulating layer 150. The gate insulating layer 150 preferably has a composition close to the stoichiometric ratio. Further, the gate insulating layer 150 preferably has few defects. For example, an oxide in which few defects are observed when evaluated by electron spin resonance (ESR) may be used for the gate insulating layer 150.

The oxide semiconductor layer 140 has a polycrystalline structure including multiple crystal grains. Although the details are described later, the oxide semiconductor layer 140 having a polycrystalline structure can be formed by using a Poly-OS (Poly-crystalline Oxide Semiconductor) technology. Although the structure of the oxide semiconductor layer 140 is described below, an oxide semiconductor having a polycrystalline structure may be referred to as a Poly-OS.

### [2. Configuration of Oxide Semiconductor Layer 140]

### [2-1. Composition Ratio of Oxide Semiconductor Layer 140]

An oxide semiconductor containing two or more metal elements including indium (In) is used for the oxide semiconductor layer 140. In the oxide semiconductor layer 140, the atomic ratio of the indium to the two or more metal elements is greater than or equal to 50%. Gallium (Ga), zinc (Zn), aluminum (Al), hafnium (Hf), yttrium (Y), zirconium (Zr), and lanthanoids are used as metal elements other than indium. However, as long as the oxide semiconductor layer 140 includes a Poly-OS, the oxide semiconductor layer 140 may contain a metal element other than the above metal elements.

### [2-2. Crystal Structure of Oxide Semiconductor Layer 140]

The oxide semiconductor layer 140 includes a Poly-OS. The crystal grain size of the crystal grain included in the Poly-OS observed from the top surface of the oxide semiconductor layer 140 (or from the thickness direction of the oxide semiconductor layer 140) or from the cross section of the oxide semiconductor layer 140 is greater than or equal to 0.1 μm, preferably greater than or equal to 0.3 μm, and more preferably greater than or equal to 0.5 μm. The crystal grain size of the crystal grain can be obtained by, for example, cross-sectional SEM observation, cross-sectional TEM observation, or an electron back scattered diffraction (EBSD) method.

The thickness of the oxide semiconductor layer 140 is greater than or equal to 10 nm and less than or equal to 100 nm, preferably greater than or equal to 15 nm and less than or equal to 70 nm, and more preferably greater than or equal to 20 nm and less than or equal to 40 nm. As described above, since the crystal grain included in the Poly-OS has a crystal grain size greater than or equal to 0.1 μm, the oxide semiconductor layer 140 includes a region including only one crystal grain in the thickness direction.

In the Poly-OS, a plurality of crystal grains may have one type of crystal structure, or may have a plurality of types of crystal structures. The crystal structure of the Poly-OS can be specified using an electron diffraction method, an XRD method, or the like. That is, the crystal structure of the oxide semiconductor layer 140 can be specified using the electron diffraction method, the XRD method, or the like.

The crystal structure of the oxide semiconductor layer 140 is preferably cubic. A cubic crystal has a highly symmetrical crystal structure, and even when oxygen vacancies are generated in the oxide semiconductor layer 140, structural relaxation is unlikely to occur, and the crystal structure is stable. As described above, by increasing the ratio of the indium element, the crystal structure of each of the plurality of crystal grains is controlled, and the oxide semiconductor layer 140 having a cubic crystal structure can be formed.

As described above, the oxide semiconductor layer 140 includes the first region 141 corresponding to the channel region CH and the second region 142 corresponding to each of the source region S and the drain region D. In the oxide semiconductor layer 140, the first region 141 has a first crystal structure and the second region 142 has a second crystal structure. Although the second region 142 has greater electrical conductivity than the first region 141, the second crystal structure is identical to the first crystal structure. Here, that two crystal structures are the same means that the crystal systems are the same. For example, when the crystal structure of the oxide semiconductor layer 140 is cubic, the first crystal structure of the first region 141 and the second crystal structure of the second region 142 are both cubic and the same. The first crystal structure and the second crystal structure can be specified using, for example, an ultrafine electron diffraction method.

Further, in a predetermined crystal orientation, the interplanar distance (d value) of the first crystal structure and the interplanar distance (d value) of the second crystal structure are substantially the same. Here, two interplanar distances (d values) are substantially the same means that one interplanar distance (d value) is greater than or equal to 0.95 times and less than or equal to 1.05 times than the other interplanar distance (d value). Alternatively, it means the case where two diffraction patterns are almost the same in the ultrafine electron diffraction method.

A grain boundary may not exist between the first region 141 and the second region 142. Further, one crystal grain may include the first region 141 and the second region 142. In other words, the change from the first region 141 to the second region 142 may be a continuous change in the crystal structure.

### [2-3. Configuration of Second Region 142]

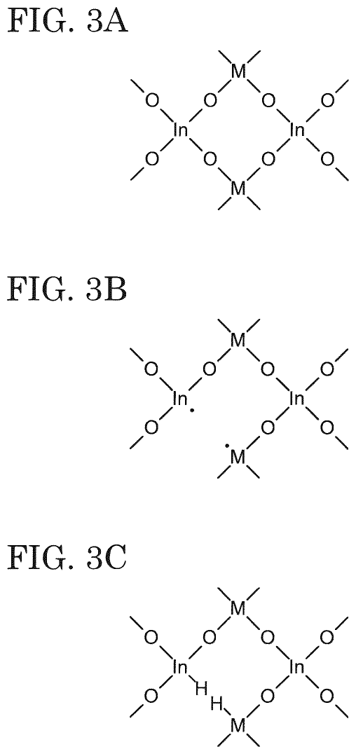

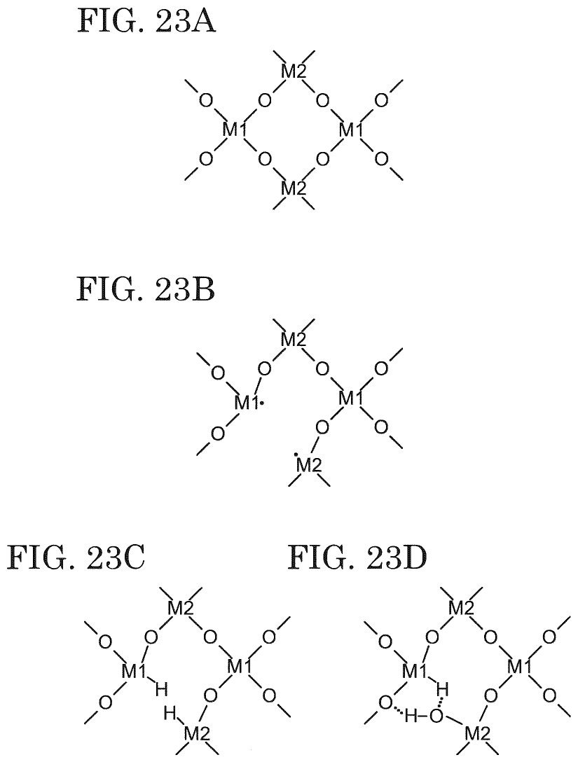

FIGS. 3A to 3C are schematic diagrams illustrating bonding states of the Poly-OS included in the second region 142 of the oxide semiconductor layer 140 of the semiconductor device 10 according to an embodiment of the present invention. FIGS. 3A to 3C show the Poly-OS containing an indium atom (In atom) and a metal atom (M atom) different from an In atom. For comparison, FIGS. 23A to 23D are schematic diagrams illustrating bonding states of an oxide semiconductor included in the second region of the oxide semiconductor layer of the conventional semiconductor device. FIGS. 23A to 23D show the oxide semiconductor containing a first metal atom M1 and a second metal atom M2. In the following description, although the oxide semiconductors illustrated in FIGS. 23A to 23D are also explained as crystalline for convenience, the oxide semiconductors illustrated in FIGS. 23A to 23D may also be amorphous. In the following description, a conventional oxide semiconductor is referred to as a Conv-OS in order to distinguish the Conv-OS from the Poly-OS.

In the Poly-OS shown in FIG. 3A, each of the In atom and the M atom is bonded to an oxygen atom (O atom). In the second region 142 of the crystal structure of the poly-OS shown in FIG. 3A, the bond between the In atom or the M atom and the O atom is cut, and an oxygen vacancy in which the O atom is desorbed is generated in order to make the electrical conductivity higher than in the first region 141 (see FIG. 3B). Since the Poly-OS contains a crystal grain with a large crystal grain size, a long-range order is easily maintained. Therefore, even when the oxygen vacancy is generated, structural relaxation hardly occurs, and the positions of the In atom and the M atom hardly change. In the state shown in FIG. 3B, when hydrogen exists, each dangling bond of the In atom and the M atom in the oxygen vacancy is bonded to a hydrogen atom (H atom) and is stabilized (see FIG. 3C). Since the H atom in the oxygen vacancies functions as a donor, the carrier concentration in the second region 142 increases.

Further, as shown in FIG. 3C, in the Poly-OS, even if the H atom is bonded in oxygen vacancies, the positions of the In atom and the M atom hardly change. Therefore, the second crystal structure of the second region 142 does not change from the crystal structure of Poly-OS without oxygen vacancies. That is, the second crystal structure of the second region 142 is the same as the first crystal structure of the first region 141.

In the Conv-OS shown in FIG. 23A, each of the first metal atom (M1 atom) and the second metal atom (M2 atom) is bound to an O atom. In the second region, the bond between the M1 atom or M2 atom and the O atom is cut, and an oxygen vacancy in which the O atom is desorbed is generated (see FIG. 23B). In the Conv-OS, when the oxygen vacancy is generated, structural relaxation occurs and the disturbance of the crystal occurs. When hydrogen exits in the state shown in FIG. 23B, each dangling bond of the M1 atom and the M2 atom is bonded to the H atom and is stabilized (see FIG. 23C). However, in the Conv-OS, structural relaxation can easily occur. Therefore, the state of the oxygen vacancy in the Conv-OS can take various states in addition to the state shown in FIG. 23C. For example, in the oxygen vacancy, the dangling bond of the M1 atom and the dangling bond of the M2 atom may be stabilized by bonding with a hydroxyl group larger than the H atom (see FIG. 23D).

As shown in FIGS. 23C and 23D, in the Conv-OS, the crystal structure of the second region is different from the crystal structure of the first region because various structures can be formed when oxygen vacancies are generated. In Conv-OS, even when the first region is crystalline, the second region is mostly amorphous.

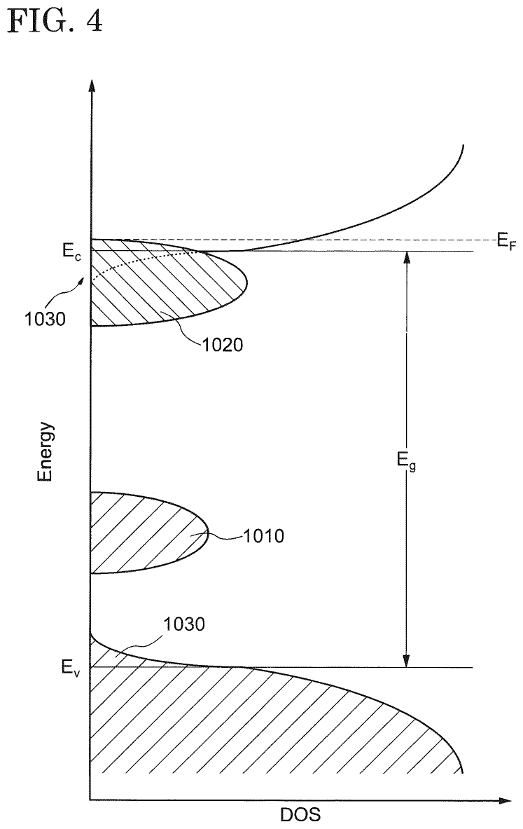

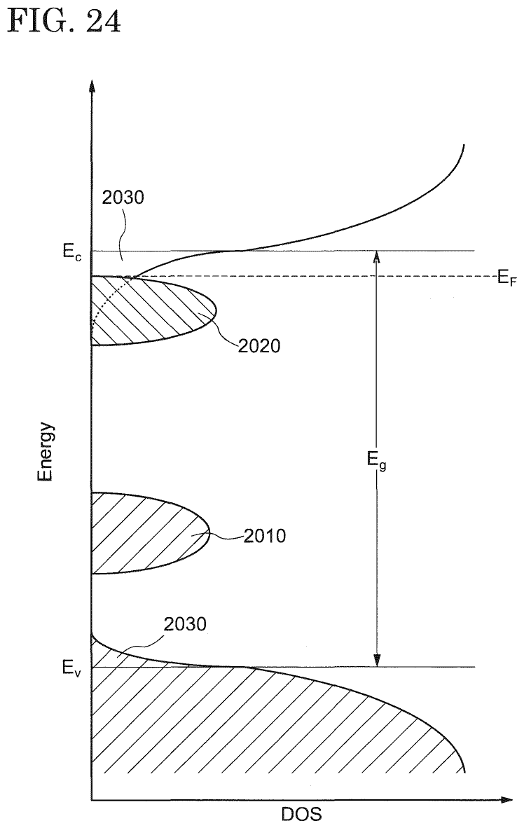

FIG. 4 is a band diagram illustrating a band structure of the second region 142 of the oxide semiconductor layer 140 of the semiconductor device 10 according to an embodiment of the invention. For comparison, FIG. 24 shows a band diagram illustrating a band structure of the second region of the oxide semiconductor layer of the conventional semiconductor device.

As shown in FIG. 4, the Poly-OS of the second region 142 includes a first energy level 1010 and a second energy level 1020 in the bandgap E_{g}. Further, tail levels 1030 are included in the vicinity of the energy level Eᵥ at the upper end of the valence band and in the vicinity of the energy level E_{c} at the lower end of the conduction band. The first energy level 1010 is a deep trap level that exists in the bandgap E_{g} and is due to oxygen vacancies. The second energy level 1020 is a donor level in the vicinity of the lower end of the conduction band and is due to hydrogen atoms bonded in oxygen vacancies. The tail levels 1030 are due to a disturbance in the long-range order.

Although the Poly-OS in the second region 142 includes the oxygen vacancies, the second region 142 has the crystalline structure and maintains the long-range order. Further, in the Poly-OS in the second region 142, the hydrogen atoms can be bonded in the oxygen vacancies without causing the structural disturbance. Therefore, the density of state (DOS) of the second energy level 1020 can be increased while suppressing the DOS of the tail level 1030. Therefore, the DOS of the second energy level 1020 is greater than the DOS of the tail level 1030 in the vicinity of the lower end of the conduction band, and the DOS of the second energy level 1020 can exceed the energy level E_{c}. That is, the Fermi level E_{F} exceeds the energy level E_{c} of the lower end of the conduction band, and the Poly-OS in the second region 142 has metallic properties.

As shown in FIG. 24, in the Conv-OS in the second region includes a first energy level 2010 and a second energy level 2020 in the bandgap E_{g}. Further, tail levels 2030 are included in the vicinity of the energy level Eᵥ at the upper end of the valence band and in the vicinity of the energy level E_{c} at the lower end of the conduction band.

In the Conv-OS in the second region, the long-range order is not maintained due to the occurrence of the structural relaxation when the oxygen vacancies are included. Further, the hydrogen atoms in the oxygen vacancies are bonded in various states, and the structural disturbance increases when the number of the hydrogen atoms in the oxygen vacancies increases. Therefore, when the DOS of the second energy level 2020 increases, the DOS of the tail level 2030 in the vicinity of the lower end of the conduction band also increases. Therefore, the DOS at the second energy level 2020 cannot exceed the energy level E_{c} at the lower end of the conduction band. That is, the Fermi level E_{F} does not exceed the energy level E_{c} at the lower end of the conduction band, and the Conv-OS in the second region has semiconductive properties with activation energy.

As described above, the Poly-OS in the second region 142 has metallic properties different from the Conv-OS which has semiconductive properties. Therefore, the resistance of the second region 142 can be sufficiently lowered by generating the oxygen vacancies. The sheet resistance of the second region 142 is less than or equal to 1000 Ohm/sq., preferably less than or equal to 500 Ohm/sq., more preferably 250 Ohm/sq. A method for generating the oxygen defects is described later.

Although the configuration of the semiconductor device 10 is described above, the semiconductor device 10 described above is a so-called top-gate transistor. The semiconductor device 10 can be modified in various ways. For example, when the light shielding layer 105 has conductivity, the semiconductor device 10 may have a structure in which the light shielding layer 105 functions as a gate electrode, and the first insulating layer 110 and the second insulating layer 120 function as gate insulating layers. In this case, the semiconductor device 10 is a so-called dual-gate transistor. Further, when the light shielding layer 105 has conductivity, the light shielding layer 105 may be a floating electrode and may be connected to the source electrode 201. Furthermore, the semiconductor device 10 may be a so-called bottom-gate transistor in which the light shielding layer 105 functions as a main gate electrode.

### [3. Method for Manufacturing Semiconductor Device 10]

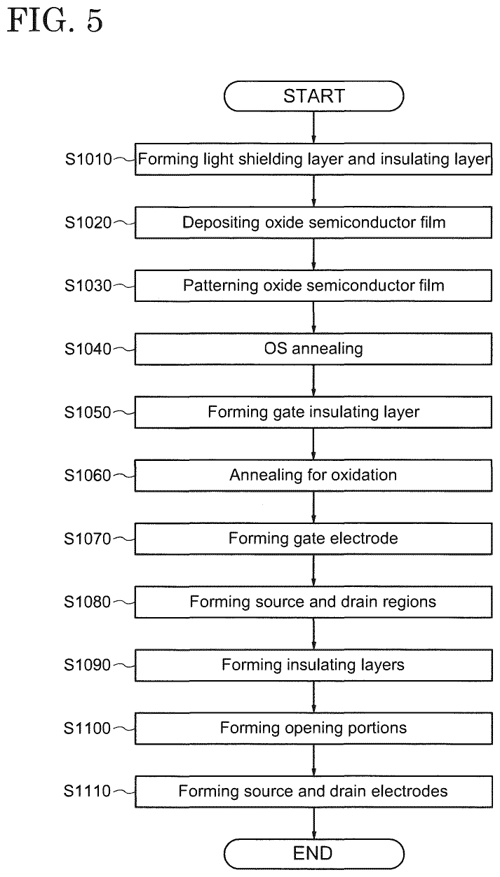

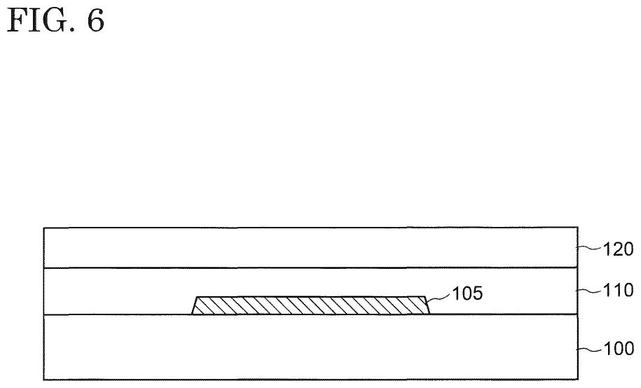

A method for manufacturing the semiconductor device 10 according to an embodiment of the present invention is described with reference to FIGS. 5 to 12. FIG. 5 is a flow chart showing a method for manufacturing the semiconductor device 10 according to an embodiment of the present invention. FIGS. 6 to 12 are schematic cross-sectional views showing the method of manufacturing the semiconductor device 10 according to an embodiment of the present invention.

As shown in FIG. 5, the method for manufacturing the semiconductor device 10 includes steps S1010 to S1110. In the following description, although the steps S1010 to S1110 are described in order, the order of the steps may be interchanged in the method for manufacturing the semiconductor device 10. Further, the method for manufacturing the semiconductor device 10 may include additional steps.

In the step S1010, the light shielding layer 105 having a predetermined pattern is formed on the substrate 100. The patterning of the light shielding layer 105 is performed using a photolithographic method. The first insulating layer 110 and the second insulating layer 120 are formed on the light shielding layer 105 (see FIG. 6). The first insulating layer 110 and the second insulating layer 120 are deposited using a CVD method. For example, silicon nitride and silicon oxide are deposited as the first insulating layer 110 and the second insulating layer 120, respectively. When silicon nitride is used for the first insulating layer 110, the first insulating layer 110 can block impurities that diffuse from the substrate 100 into the oxide semiconductor layer 140. When silicon oxide is used for the second insulating layer 120, the second insulating layer 120 can release oxygen by a heat treatment.

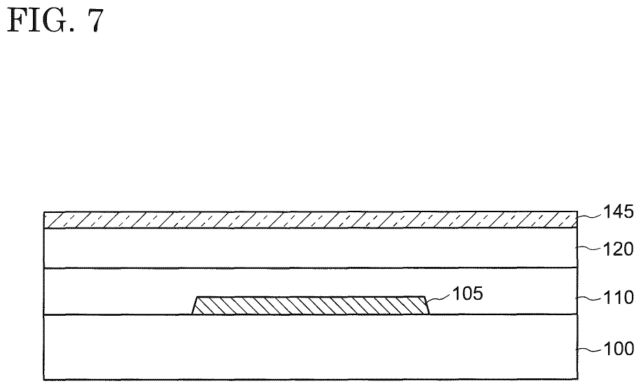

In the step S1020, an oxide semiconductor film 145 is formed on the second insulating layer 120 (see FIG. 7). The oxide semiconductor film 145 is deposited by a sputtering method. The thickness of the oxide semiconductor film 145 is, for example, greater than or equal to 10 nm and less than or equal to 100 nm, preferably greater than or equal to 15 nm and less than or equal to 70 nm, and more preferably greater than or equal to 20 nm and less than or equal to 40 nm.

The oxide semiconductor film 145 in the step S1020 is amorphous. In the Poly-OS technology, the oxide semiconductor film 145 after the deposition and before the heat treatment is preferably amorphous so that the oxide semiconductor layer 140 has a uniform polycrystalline structure in the substrate plane. Therefore, the deposition conditions of the oxide semiconductor film 145 are preferably conditions under which the oxide semiconductor layer 140 immediately after the deposition is not crystallized as much as possible. When the oxide semiconductor film 145 is formed by the sputtering method, the oxide semiconductor film 145 is deposited while controlling the temperature of the object to be deposited (the substrate 100 and the layers formed thereon) to less than or equal to 100° C., and preferably less than or equal to 50° C. Further, the oxide semiconductor film 145 is deposited under a condition of low oxygen partial pressure. The oxygen partial pressure is greater than or equal to 2% and less than or equal to 20%, preferably greater than or equal to 3% and less than or equal to 15%, and more preferably greater than or equal to 3% and less than or equal to 10%.

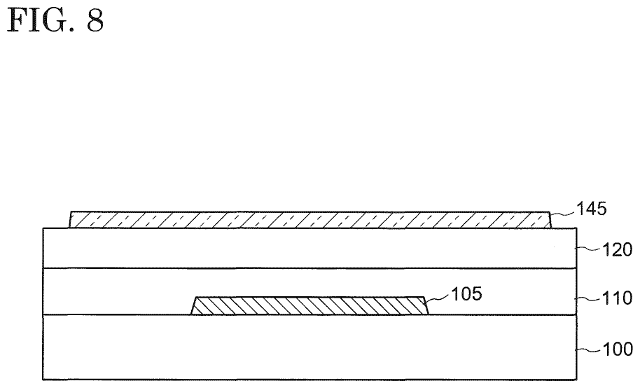

In the step S1030, the oxide semiconductor film 145 is patterned (see FIG. 8). The patterning of the oxide semiconductor film 145 is performed using a photolithography method. Wet etching or dry etching may be used for the etching of the oxide semiconductor film 145. The wet etching can be performed using an acidic etchant. For example, oxalic acid, PAN, sulfuric acid, hydrogen peroxide solution, hydrofluoric acid, or the like can be used for the etchant.

In the step S1040, a heat treatment is performed on the oxide semiconductor film 145. Hereinafter, the heat treatment performed in step S1040 is referred to as “OS annealing”. In the OS annealing, the oxide semiconductor film 145 is held at a predetermined reaching temperature for a predetermined time. The predetermined reaching temperature is higher than or equal to 300° C. and lower than or equal to 500° C., and preferably higher than or equal to 350° C. and lower than or equal to 450° C. The holding time at the reaching temperature is greater than or equal to 15 minutes and less than or equal to 120 minutes, and preferably greater than or equal to 30 minutes and less than or equal to 60 minutes. The oxide semiconductor film 145 is crystallized to form the oxide semiconductor layer 140 having a polycrystalline structure by the OS annealing.

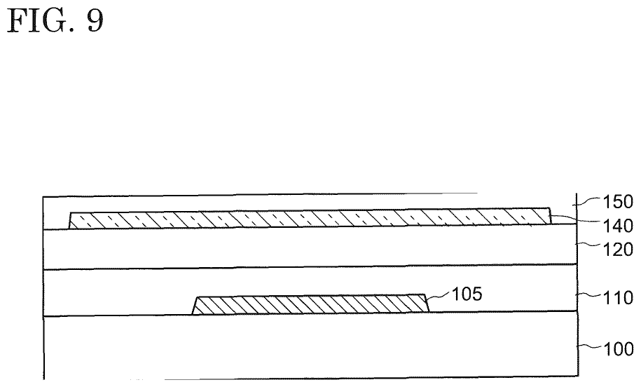

In the step S1050, the gate insulating layer 150 is deposited on the oxide semiconductor layer 140 (see FIG. 9). The gate insulating layer 150 is deposited using the CVD method. For example, silicon oxide is deposited for the gate insulating layer 150. In order to reduce defects in the gate insulating layer 150, the gate insulating layer 150 may be deposited at a deposition temperature of higher than or equal to 350° C. The thickness of the gate insulating layer 150 is greater than or equal to 50 nm and less than or equal to 300 nm, preferably greater than or equal to 60 nm and less than or equal to 200 nm, and more preferably greater than or equal to 70 nm and less than or equal to 150 nm. After the gate insulating layer 150 is deposited, a treatment for introducing oxygen into a part of the gate insulating layer 150 may be performed.

In the step S1060, a heat treatment is performed on the oxide semiconductor layer 140. Hereinafter, the heat treatment performed in step S1060 is referred to as “oxidation annealing”. When the gate insulating layer 150 is formed on the oxide semiconductor layer 140, many oxygen vacancies are generated on the top surface and side surfaces of the oxide semiconductor layer 140. When oxidation annealing is performed, oxygen is supplied from the second insulating layer 120 and the gate insulating layer 150 to the oxide semiconductor layer 140, and oxygen vacancies are repaired.

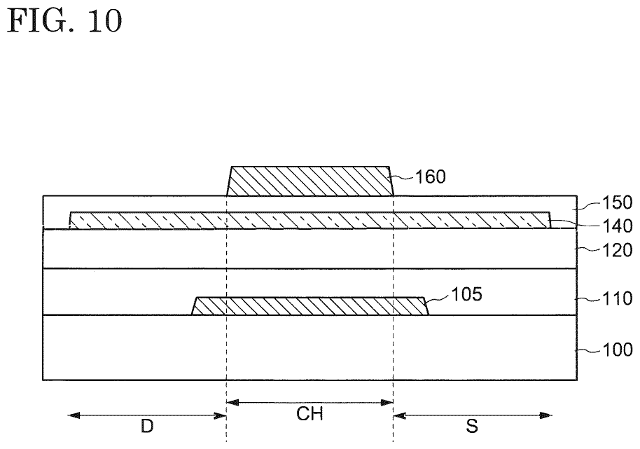

In the step S1070, the gate electrode 160 having a predetermined pattern is formed on the gate insulating layer 150 (see FIG. 10). The gate electrode 160 is deposited by the sputtering method or an atomic layer deposition method, and patterning of the gate electrode 160 is performed using the photolithographic method.

In the step S1080, the source region S and the drain region D are formed in the oxide semiconductor layer 140 (see FIG. 10). The source region S and the drain region D are formed by ion implantation. Specifically, impurities are implanted into the oxide semiconductor layer 140 through the gate insulating layer 150 using the gate electrode 160 as a mask. For example, boron (B), phosphorus (P), argon (Ar), or the like is used as the implanted impurity. Oxygen vacancies are generated by the ion implantation in the source region S and the drain region D that do not overlap the gate electrode 160, so that the resistance of the source region S and the drain region D (that is, the second region 142) is lowered. On the other hand, in the channel region CH (that is, the first region 141) that overlaps the gate electrode 160, no impurities are implanted, so the resistance of the channel region CH does not decrease. Further, hydrogen is trapped in the source region S and the drain region D due to oxygen vacancies formed in the source region S and the drain region D. As a result, the resistance of the source region S and the drain region D is sufficiently reduced.

In addition, in the semiconductor device 10, since impurities are implanted into the oxide semiconductor layer 140 through the gate insulating layer 150, impurities such as boron (B), phosphorus (P), or argon (Ar) are included in the gate insulating layer 150.

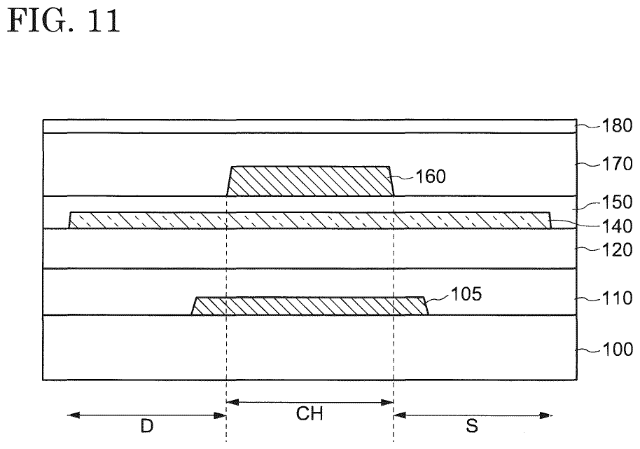

In the step S1090, the third insulating layer 170 and the fourth insulating layer 180 are formed over the gate insulating layer 150 and the gate electrode 160 (see FIG. 11). The third insulating layer 170 and the fourth insulating layer 180 are deposited using the CVD method. For example, silicon oxide and silicon nitride are deposited for the third insulating layer 170 and the fourth insulating layer 180, respectively. The thickness of the third insulating layer 170 is greater than or equal to 50 nm and less than or equal to 500 nm. The thickness of the fourth insulating layer 180 is also greater than or equal to 50 nm and less than or equal 500 nm or less.

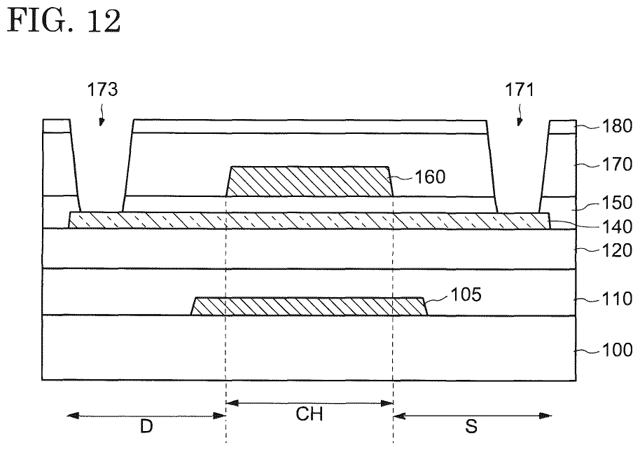

In the step S1100, the opening portions 171 and 173 are formed in the gate insulating layer 150, the third insulating layer 170, and the fourth insulating layer 180 (see FIG. 12). The source region S and the drain region D of the oxide semiconductor layer 140 is exposed by the formation of the opening portions 171 and 173.

In the step S1110, the source electrode 201 is formed on the fourth insulating layer 180 and inside the opening portion 171, and the drain electrode 203 is formed on the fourth insulating layer 180 and inside the opening portion 173. The source electrode 201 and the drain electrode 203 are formed as the same layer. Specifically, the source electrode 201 and the drain electrode 203 are formed by patterning one deposited conductive film. The semiconductor device 10 shown in FIG. 1 is manufactured through the above steps.

As described above, in the semiconductor device 10 according to the present embodiment, the oxide semiconductor layer 140 includes the Poly-OS, and not only the channel region CH but also the source region S and the drain region D have a crystalline structure. Thus, the resistance of the source region S and the drain region D can be sufficiently reduced. Therefore, the parasitic resistance of the source region S and the drain region D is reduced, and variations in an on-current in the electrical characteristics of the semiconductor device 10 can be suppressed. Since the semiconductor device 10 has a high mobility, a display device using the semiconductor device 10 is suppressed in variation and improved in performance.

### Second Embodiment

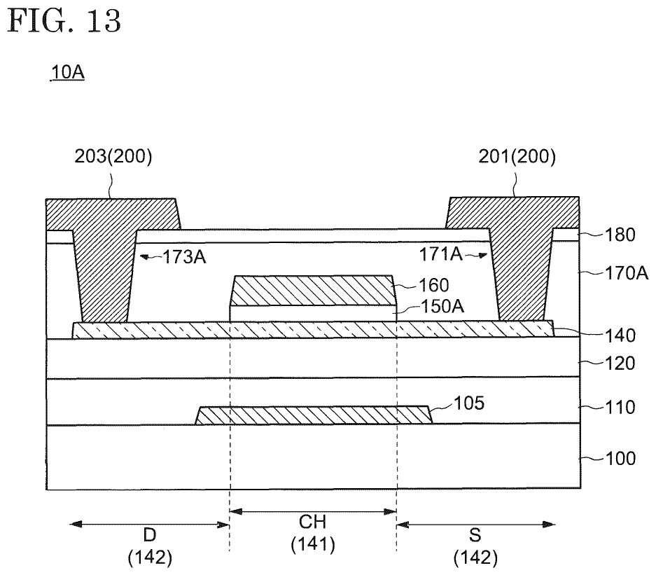

A semiconductor device 10A according to an embodiment of the present invention is described with reference to FIGS. 13 to 23. When a configuration of the semiconductor device 10A is the same as the configuration of the semiconductor device 10, the description of the configuration of the semiconductor device 10A may be omitted.

### [1. Configuration of Semiconductor Device 10A]

FIG. 13 is a schematic cross-sectional view showing a configuration of the semiconductor device 10A according to an embodiment of the present invention.

As shown in FIG. 13, the semiconductor device 10A includes the substrate 100, the light shielding layer 105, the first insulating layer 110, the second insulating layer 120, the oxide semiconductor layer 140, a gate insulating layer 150A, the gate electrode 160, a third insulating layer 170A, the fourth insulating layer 180, the source electrode 201, and the drain electrode 203.

Although the gate insulating layer 150A is provided on the oxide semiconductor layer 140, a part of the oxide semiconductor layer 140 is exposed from the gate insulating layer 150A. The gate insulating layer 150A overlaps the gate electrode 160, and an edge portion of the gate insulating layer 150A substantially coincides with the edge of the gate electrode 160. The third insulating layer 170A is provided on the second insulating layer 120 to cover the upper surface and the end surface of the gate electrode 160, an end surface of the gate insulating layer 150A, and the upper surface and the end surface of the oxide semiconductor layer 140. Opening portions 171A and 173 through which a part of the upper surface of oxide semiconductor layer 140 is exposed are provided in the third insulating layer 170A and the fourth insulating layer 180. The source electrode 201 is provided on the fourth insulating layer 180 and inside the opening portion 171A and is in contact with the oxide semiconductor layer 140. Similarly, the drain electrode 203 is provided on the fourth insulating layer 180 and inside the opening portion 173A and is in contact with the oxide semiconductor layer 140.

In the semiconductor device 10A as well, the oxide semiconductor layer 140 includes the first region 141 corresponding to the channel region CH and the second region 142 corresponding to the source region S or the drain region D. The first region 141 has the first crystal structure and the second region 142 has the second crystal structure. Therefore, in the semiconductor device 10A as well, the resistance of the source region S and the drain region D is sufficiently reduced.

### [2. Method for Manufacturing Semiconductor Device 10A]

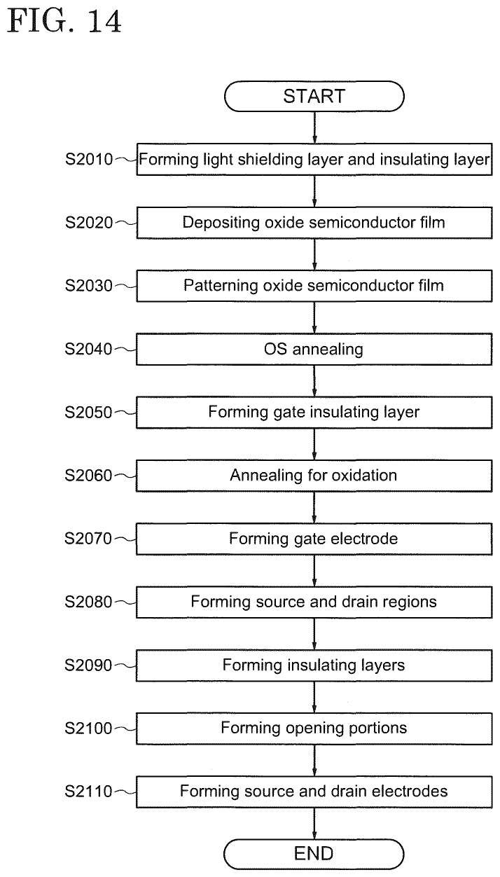

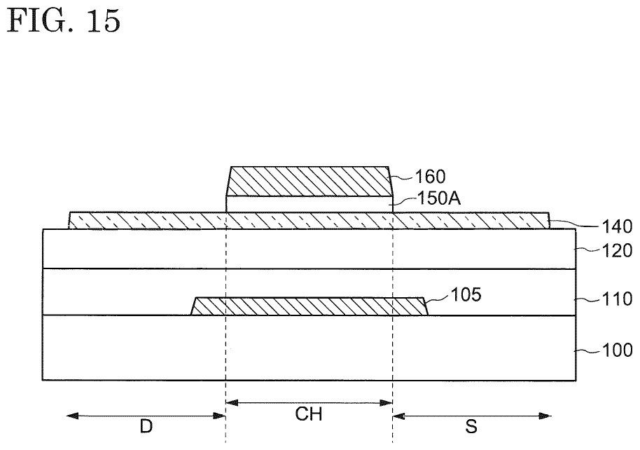

A method for manufacturing the semiconductor device 10A according to an embodiment of the present invention is described with reference to FIGS. 14 to 17. FIG. 14 is a flow chart showing a method of manufacturing the semiconductor device 10A according to an embodiment of the present invention. FIGS. 15 to 17 are schematic cross-sectional views showing the manufacturing method of the semiconductor device 10A according to an embodiment of the present invention.

As shown in FIG. 14, the method for manufacturing the semiconductor device 10A includes steps S2010 to S2110. Since the steps S2010 to S2060 are the same as the steps S1010 to S1060 described in the first embodiment, respectively, the descriptions thereof are omitted.

In the step S2070, the gate electrode 160 having a predetermined pattern is formed on the oxide semiconductor layer 140, and the gate insulating layer 150A is formed using the gate electrode 160 as a mask (see FIG. 15). As a result, the top surface and the end surface of the oxide semiconductor layer 140 are exposed from the gate insulating layer 150A.

In the step S2080, the source region S and the drain region D are formed in the oxide semiconductor layer 140 (see FIG. 15). The source region S and the drain region D are formed by ion implantation. Specifically, impurities are directly implanted into the oxide semiconductor layer 140 using the gate electrode 160 and the gate insulating layer 150A as a mask. Oxygen vacancies are formed in the source region S and the drain region D, and hydrogen is trapped in the source region S and the drain region D. As a result, the resistance of the source region S and the drain region D is sufficiently reduced.

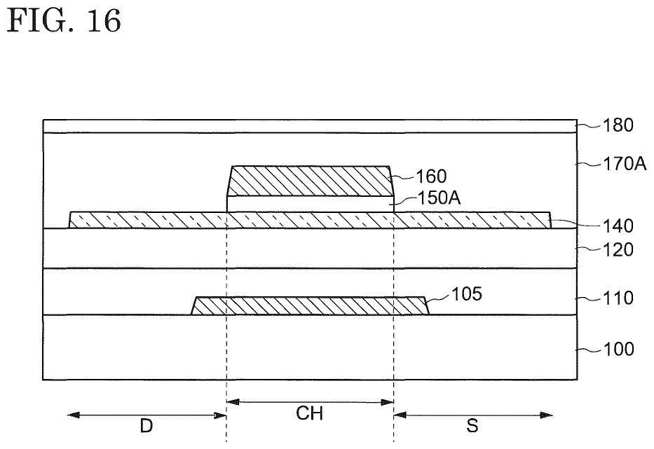

The third insulating layer 170A and the fourth insulating layer 180 are formed over the oxide semiconductor layer 140 and the gate electrode 160 (see FIG. 16). The third insulating layer 170A is in contact with the upper surface and the end surface of the oxide semiconductor layer 140 which are exposed from the gate insulating layer 150A.

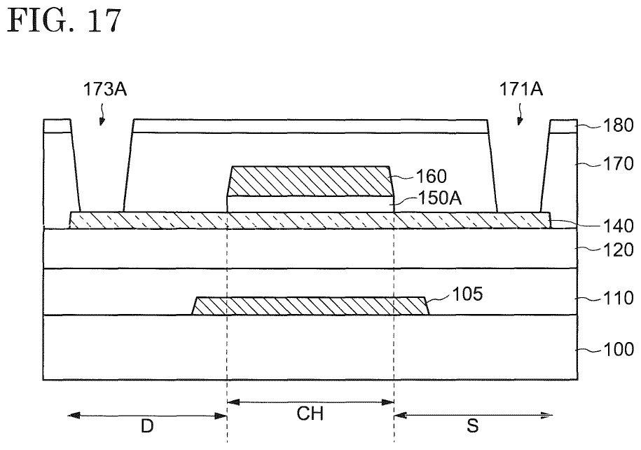

In the step S2100, the opening portions 171A and 173A are formed in the third insulating layer 170A and the fourth insulating layer 180 (see FIG. 17). The source region S and the drain region D of the oxide semiconductor layer 140 are exposed by forming the opening portions 171A and 173A.

In the step S2110, the source electrode 201 is formed on the fourth insulating layer 180 and inside the opening portion 171A, and the drain electrode 203 is formed on the fourth insulating layer 180 and inside the opening portion 173A. The semiconductor device 10A shown in FIG. 13 is manufactured through the above steps.

As described above, in the semiconductor device 10A according to the present embodiment, the oxide semiconductor layer 140 includes the Poly-OS, and not only the channel region CH but also the source region S and the drain region D have a crystalline structure. Thus, the resistance of the source region and the drain region D can be sufficiently reduced. Therefore, the parasitic resistance of the source region S and the drain region D is reduced, and variations in an on-current in the electrical characteristics of the semiconductor device 10A can be suppressed. Since the semiconductor device 10A has a high mobility, a display device using the semiconductor device 10 is suppressed in variation and improved in performance.

### EXAMPLE

The semiconductor device 10 is described in more detail based on the manufactured samples. The example described below is one example of the semiconductor device 10, and the configuration of the semiconductor device 10 is not limited to the configuration of the example described below.

### [1. Example Sample]

### [1-1. Manufacture of Example Sample]

As an example sample, the semiconductor device 10 was manufactured using the manufacturing method described in the first embodiment. In the example sample, the oxide semiconductor layer 140 contained indium, and the atomic ratio of the indium element to all metal elements was greater than or equal to 50%. Further, although the oxide semiconductor layer 140 was amorphous before the OS annealing, the oxide semiconductor layer 140 was crystallized after the OS annealing to have a polycrystalline structure. That is, the oxide semiconductor layer 140 of the example sample included the Poly-OS. Using the gate electrode 160 as a mask, boron was implanted into the oxide semiconductor layer 140 through the gate insulating layer 150 to form the first region 141 and the second region 142 in the oxide semiconductor layer 140.

### [1-2. Cross-Sectional TEM Observation]

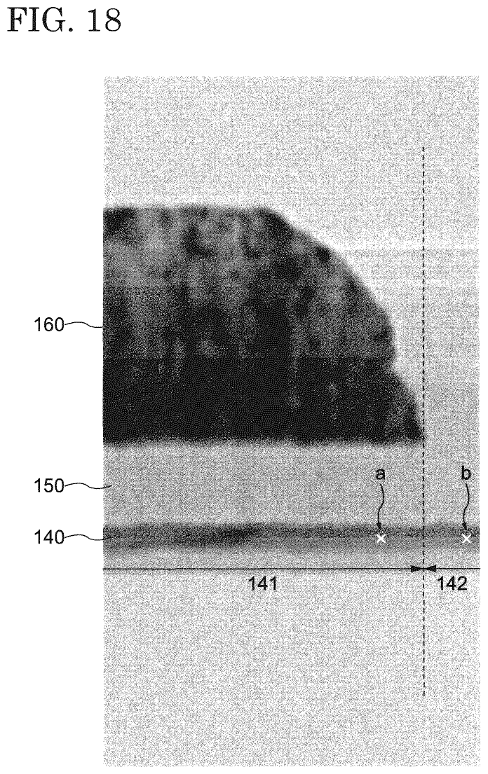

FIG. 18 is a cross-sectional TEM image of the semiconductor device 10 (example sample) according to the example. FIG. 18 shows a cross-sectional TEM image near the end surface of the gate electrode 160. The oxide semiconductor layer 140 included a crystal grain with the grain size greater than or equal to 0.3 μm. Further, no grain boundary was observed between the first region 141 and the second region 142. That is, one crystal grain was formed so as to include the first region 141 and the second region 142.

### [1-3. Ultrafine Electron Diffraction]

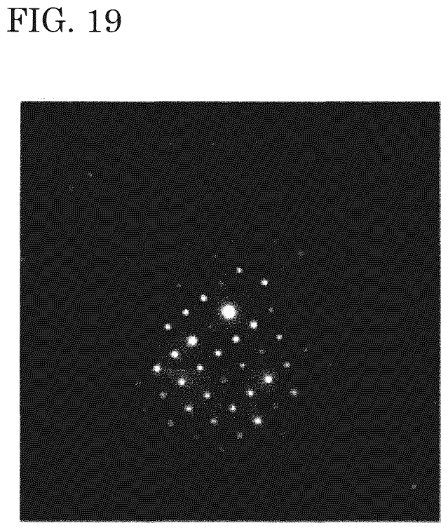

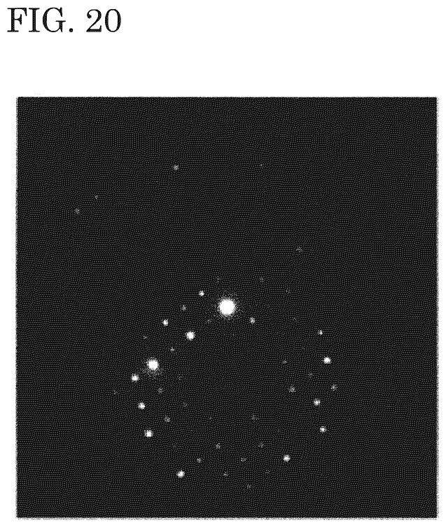

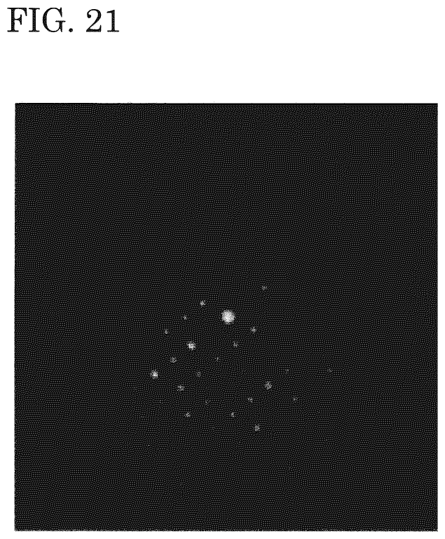

FIGS. 19 to 21 show diffraction patterns of the semiconductor device 10 (example sample) according to the example observed using ultrafine electron diffraction. FIG. 19 is a diffraction pattern observed at point a shown in FIG. 18, and FIG. 20 is a diffraction pattern observed at point b shown in FIG. 18. FIG. 21 is a diffraction pattern obtained by overlapping the diffraction pattern shown in FIG. 19 and the diffraction pattern shown in FIG. 20. In FIG. 21, the diffraction pattern of FIG. 19 is shown in green and the diffraction pattern of FIG. 20 is shown in red.

The points a and b are included in the first region 141 and the second region 142, respectively. As shown in FIGS. 19 and 20, the diffraction patterns attributed to the crystal structure are observed at the points a and b. Analysis of the diffraction pattern shows that the crystal structure of each of the points a and b is cubic. Although there is a difference in intensity between the diffraction pattern shown in FIG. 19 and the diffraction pattern shown in FIG. 20, the two diffraction patterns almost match as shown in FIG. 21. That is, it is found that the interplanar distance (d value) of the first crystal structure of the first region 141 and the interplanar distance (d value) of the second crystal structure of the second region 142 are substantially the same. In addition, in FIG. 21, the points where the intensities are almost the same and the two diffraction patterns match are shown in yellow.

### [1-4. Sheet Resistance Measurement]

The sheet resistance of the second region 142 of the example sample was 210 Ohm/sq. In addition, the thickness of the oxide semiconductor layer 140 was 30 nm.

### [1-5. Electrical Characteristics]

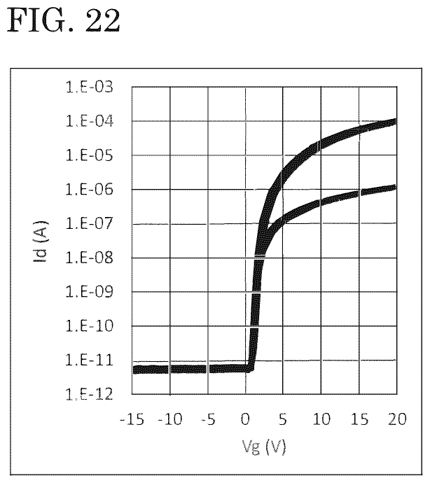

FIG. 22 is a graph showing electrical characteristics of the semiconductor device 10 (example sample) according to the example. FIG. 22 shows electrical characteristics of 19 example samples having a channel width W/channel length L=3 μm/3 μm. The vertical axis of the graph shown in FIG. 22 indicates the drain current Id, and the horizontal axis indicates the gate voltage Vg. Table 1 shows the measurement conditions for the electrical characteristics of the example samples.

TABLE 1

| | |
|---|---|
| Source-drain voltage | 0.1 V (dotted line), 10 V (solid line) |
| gate voltage | −15 V to +20 V |
| Measurement | room temperature, darkroom |
| environment | |

As shown in FIG. 22, no decrease in an on-current is observed in the example samples. Further, in the example samples, the variation in the on-state current was suppressed.

### [2. Comparative Sample]

### [2-1. Manufacture of Comparative Sample]

As a comparative sample, a semiconductor device including an amorphous oxide semiconductor was manufactured using the same manufacturing method as the example sample. That is, the comparative sample has the same structure as the example sample except for the oxide semiconductor layer. In the comparative sample, the oxide semiconductor layer contained indium gallium zinc oxide (IGZO), and the atomic ratio of indium to all metal elements was about 33%. The oxide semiconductor layer of the comparative sample was amorphous even after the OS annealing. That is, both the first region and the second region of the oxide semiconductor layer were amorphous.

### [2-2. Sheet Resistance Measurement]

The sheet resistance of the second region of the comparative sample was 2340 Ohm/sq. In addition, the thickness of the oxide semiconductor layer was 30 nm.

### [2-3. Electrical Characteristics]

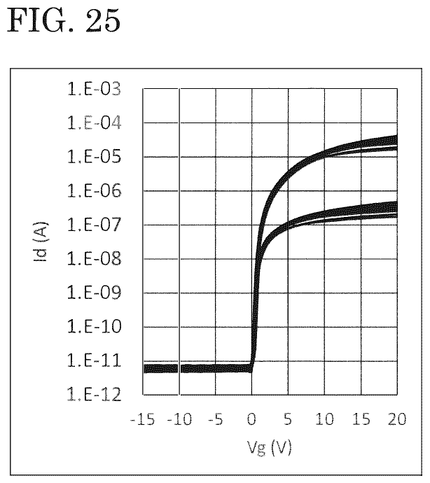

FIG. 25 is a graph showing electrical characteristics of the semiconductor device (comparative sample) according to the comparative example. FIG. 25 shows electrical characteristics of 19 comparative samples with a channel width W/channel length L=3 μm/3 μm. The vertical axis of the graph shown in FIG. 25 indicates the drain current Id, and the horizontal axis indicates the gate voltage Vg. Table 1 also shows the measurement conditions for the electrical characteristics of the comparative samples.

As shown in FIG. 25, the on-current decreases in the comparative samples. Further, variations in the on-current are observed in the comparative examples.

Based on the above results, in the example sample, the oxide semiconductor layer 140 includes the Poly-OS, and the second region 142 corresponding to each of the source region S and the drain region D is sufficiently low resistance by generating oxygen vacancies while maintaining the same crystal structure as the first region 141. In particular, in the example sample, the sheet resistance of the second region 142 is 250 Ohm/sq., which is a value that cannot be achieved with the conventional oxide semiconductor. As a result, in the example sample, the parasitic resistance of the source region S and the drain region D is reduced, and the variations in the on-current in the electrical characteristics are suppressed.

Each of the embodiments described above as an embodiment of the present invention can be appropriately combined and implemented as long as no contradiction is caused. Further, the addition, deletion, or design change of components, or the addition, deletion, or condition change of processes as appropriate by those skilled in the art based on each of embodiments are included in the scope of the present invention as long as they are provided with the gist of the present invention.

It is understood that, even if the effect is different from those provided by each of the above-described embodiments, the effect obvious from the description in the specification or easily predicted by persons ordinarily skilled in the art is apparently derived from the present invention.

What is claimed is:

1. A semiconductor device comprising:
an oxide semiconductor layer having a polycrystalline structure on an insulating surface;
a gate electrode over the oxide semiconductor layer; and
a gate insulating layer between the oxide semiconductor layer and the gate electrode,
wherein the oxide semiconductor layer comprises:
a first region having a first crystal structure overlapping the gate electrode, and
a second region having a second crystal structure not overlapping the gate electrode,
an electrical conductivity of the second region is larger than an electrical conductivity of the first region, and
the second crystal structure is identical to the first crystal structure.

2. The semiconductor device according to claim 1, wherein a d-value of the second crystal structure is substantially identical to a d-value of the first crystal structure.

3. The semiconductor device according to claim 1, wherein the first crystal structure and the second crystal structure are cubic.

4. The semiconductor device according to claim 1, wherein the first crystal structure and the second crystal structure are specified by a microelectron diffraction.

5. The semiconductor device according to claim 1, wherein a sheet resistance of the second region is less than or equal to 1000 Ohm/sq.

6. The semiconductor device according to claim 1, wherein a sheet resistance of the second region is less than or equal to 500 Ohm/sq.

7. The semiconductor device according to claim 1, wherein a grain boundary does not exist between the first region and the second region.

8. The semiconductor device according to claim 1, wherein the first region and the second region are included in one crystal grain.

9. The semiconductor device according to claim 1, wherein the second region contains at least one of boron, phosphorus, and argon.

10. The semiconductor device according to claim 1, wherein an upper surface and an edge surface of the oxide semiconductor layer is covered with the gate insulating layer.

11. The semiconductor device according to claim 10, wherein the insulating layer contains at least one of boron, phosphorus, and argon.

12. The semiconductor device according to claim 1,
wherein the oxide semiconductor layer contains at least two metal elements including an indium element, and
a ratio of the indium element to the at least two metal elements is greater than or equal to 50%.
